(19) United States
(12) Patent Application Publication
(10) Pub. No.: US 2026/0357473 A1
(43) Pub. Date: Nov. 12, 2026

(54) SURFACTANT-MEDIATED FACETED HGCDTE GROWTH METHODS AND LOW-BANDGAP PHOTOVOLTAIC DEVICES FORMED THEREFROM

(71) Applicant: Jonathan Washburn, Austin, TX (US)

(72) Inventor: Jonathan Washburn, Austin, TX (US)

(21) Appl. No.: 19/675,015

(22) Filed: May 12, 2026

Related U.S. Application Data
(60) Provisional application No. 63/804,592, filed on May 12, 2025.

(51) Int. Cl. C30B 25/16; C30B 29/48; H10F 10/14; H10F 77/12; H10F 77/70

(52) U.S. Cl. CPC C30B 25/16; C30B 29/48; H10F 10/14; H10F 77/127; H10F 77/703

(57) ABSTRACT

A method of growing low-bandgap Hg1-xCdxTe films and photovoltaic devices is disclosed. A Hg1-xCdxTe film having a bandgap between about 0.09 eV and about 0.11 eV is grown by vapor-phase epitaxy in successive portions. A surfactant-mediated morphology-control treatment, in preferred embodiments a gold-containing treatment, is periodically applied during growth, and epitaxial growth is resumed after each treatment. The repeated treatment induces ordered high-index faceted morphology in the film, in preferred embodiments self-ordered (113)B facets, and increases minority-carrier lifetime relative to a control film grown without the treatment. Photovoltaic devices formed from the film may include p-on-n, n-on-p, p-i-n, nBn, barrier-type, heterojunction, mesa, or planar junction structures. In certain embodiments the device exhibits a dark current density of not more than about 3×10\hat{ }−5 A/cm\hat{ }2 at 150 K and 200 mV bias.

### CROSS-REFERENCE TO RELATED APPLICATIONS

This application claims the benefit of priority to U.S. Provisional Patent Application 63/804,592, filed May 12, 2025, the contents of which are incorporated herein by reference in their entirety.

### BACKGROUND

The present invention relates generally to epitaxial growth of narrow-bandgap semiconductor materials and to photovoltaic devices formed therefrom. More particularly, the present invention relates to methods of growing Hg1-xCdxTe with a low bandgap in the long-wave infrared regime using surfactant-mediated morphology control during vapor-phase epitaxy, with gold-containing surfactant treatments being preferred, and to photovoltaic and long-wave infrared optoelectronic devices formed from the resulting material.

HgCdTe is a tunable II-VI semiconductor system whose bandgap can be adjusted through selection of cadmium mole fraction x. Compositions in the vicinity of x about 0.2 can provide a bandgap in the vicinity of about 0.10 eV, corresponding to long-wave infrared operation and making such material of interest for long-wave photovoltaic conversion.

Despite the utility of HgCdTe for infrared detection and thermophotovoltaic conversion, practical deployment of very low-bandgap HgCdTe remains limited by several interacting problems. The discussion of approaches in this Background is provided to place the invention in context and should not be treated as an admission regarding the scope of the prior art.

A first problem is Auger recombination. At bandgaps below about 0.15 eV, Auger recombination can dominate carrier loss, sharply reducing minority-carrier lifetime and producing dark current levels that can overwhelm useful photocurrent, particularly at elevated operating temperatures.

A second problem is that growth conditions capable of producing low-bandgap HgCdTe with useful long-wave photovoltaic performance can also lead to surface roughening, mercury loss, and nonuniform morphology or composition across the growing film.

A third problem is that conventional approaches for improving lifetime in low-bandgap HgCdTe have not consistently provided a practical and repeatable growth technique for inducing a favorable surface morphology during MOVPE growth of the absorber itself.

A fourth problem is that prior efforts directed to low-bandgap HgCdTe have often emphasized detector operation or cryogenic performance rather than photovoltaic operation using material grown to support useful long-wave infrared photovoltaic response.

Accordingly, there remains a need for a growth method for low-bandgap HgCdTe that can be implemented by vapor-phase epitaxy, including MOVPE, that can induce a repeatable favorable high-index facet morphology during growth, and that can provide improved minority-carrier lifetime in material suitable for photovoltaic device fabrication.

### SUMMARY

Disclosed herein are methods of growing low-bandgap Hg1-xCdxTe for photovoltaic and long-wave infrared optoelectronic devices using a surfactant-mediated morphology-control treatment during vapor-phase epitaxy. In preferred implementations, the epitaxy is metal-organic vapor-phase epitaxy (MOVPE), the surfactant treatment is a gold-containing treatment or periodic gold deposition, and Hg1-xCdxTe having a bandgap in the range of about 0.09 eV to about 0.11 eV is grown in successive portions so that the surfactant treatment induces ordered high-index faceted morphology in the growing material. In more particular preferred embodiments, the ordered high-index faceted morphology comprises self-ordered (113)B facets.

In certain embodiments, the gold-containing surfactant treatment comprises depositing gold in a thickness between about 1 nm and about 3 nm, exposing the growth surface to a gold-containing precursor, or otherwise providing a gold-containing surface treatment effective to modify subsequent Hg1-xCdxTe growth. In certain embodiments, the treatment is repeated after about 300 nm to about 500 nm of Hg1-xCdxTe growth, and in more particular embodiments after about 400 nm of growth.

In certain embodiments, MOVPE growth is carried out at a reactor pressure of about 40 Torr and a substrate temperature of about 345 degrees C. AFM characterization in representative implementations shows self-ordered (113)B facets having a height of about 12 nm.

In preferred embodiments, the surfactant-induced high-index faceted morphology increases minority-carrier lifetime relative to Hg1-xCdxTe grown without the surfactant treatment. In some embodiments, the minority-carrier lifetime is increased by at least five-fold. In certain embodiments, the disclosed growth method produces Hg1-xCdxTe films suitable for long-wave infrared photovoltaic devices, thermophotovoltaic devices, detector devices, and other long-wave infrared optoelectronic devices.

In preferred embodiments, periodic gold deposition constitutes the morphology-control treatment applied between successive growth portions of the Hg1-xCdxTe film. The disclosed growth method is therefore centered, in preferred examples, on periodic gold deposition during MOVPE growth, with the gold acting as a surfactant to induce self-ordered (113)B facets in the growing film. In broader embodiments, the morphology-control treatment may comprise a gold-containing surfactant exposure, a gold-containing precursor pulse, a deposited gold layer, or another surface treatment that produces an ordered high-index faceted morphology and improved minority-carrier lifetime relative to a control film grown without the treatment.

Also disclosed are Hg1-xCdxTe films produced by the disclosed process and having ordered high-index faceted morphology, including self-ordered (113)B facets in preferred embodiments, induced by periodic surfactant treatment during growth. Also disclosed are photovoltaic devices and methods of fabricating photovoltaic devices from Hg1-xCdxTe films produced by the disclosed methods. In certain embodiments, the photovoltaic device comprises a diode structure formed on the disclosed film, with a p-on-n diode structure being a preferred implementation. Alternative device structures include n-on-p, p-i-n, nBn, barrier-type, heterojunction, mesa, and planar junction structures configured for carrier separation and collection. In certain embodiments, such photovoltaic devices exhibit a dark current density of not more than about 3×10\hat{ }5 A/cm\hat{ }2 at 150 K and 200 mV bias.

In certain embodiments, such photovoltaic devices yield a short-circuit current density of at least about 0.3 A/cm\hat{ }2 at 200 K under a 400 K to 600 K black-body source.

In certain preferred embodiments, the inventive growth architecture is a segmented growth architecture in which a gold-containing morphology-control treatment is interposed between successive low-bandgap Hg1-xCdxTe growth portions. In such embodiments, the technical contribution is not merely the presence of gold at a growth surface, but the repeated sequence of low-bandgap Hg1-xCdxTe growth, interruption, gold-containing treatment, resumed epitaxial growth, and repetition at selected thickness intervals to establish and maintain an ordered high-index faceted morphology through a practical absorber thickness.

In certain embodiments, the surfactant-mediated morphology-control treatment is defined by its process placement and effect: the treatment is applied to a growth surface between successive Hg1-xCdxTe growth portions in an amount effective to modify resumed epitaxial growth and to produce an ordered high-index faceted morphology relative to a control film grown without the treatment. Gold-containing surfactant treatments are preferred because representative implementations described herein demonstrate induction of self-ordered (113)B facets and improved minority-carrier lifetime.

### BRIEF DESCRIPTION OF THE FIGURES

FIG. 1 is a graph showing HgCdTe bandgap as a function of cadmium mole fraction and identifying a target low-bandgap region for photovoltaic operation.

FIG. 2 is a schematic cross-section showing a surfactant treatment region, such as a deposited gold layer or gold-containing treatment region, during HgCdTe growth and the resulting ordered high-index faceted morphology, preferably self-ordered (113)B facet morphology.

FIG. 3 is a process flow diagram showing an illustrative vapor-phase epitaxy sequence, preferably MOVPE, with repeated surfactant treatment and resumed growth of low-bandgap HgCdTe.

FIG. 4 is a schematic cross-section of a representative photovoltaic device fabricated from the disclosed HgCdTe film.

FIG. 5 is a schematic cross-section showing a plurality of spaced treatment-interface regions within an Hg1-xCdxTe film produced by repeated surfactant-mediated morphology-control treatment during growth.

FIG. 6 is an enlarged schematic view of an ordered high-index faceted surface region of an Hg1-xCdxTe film, showing representative facet height, facet pitch, and facet orientation.

### DETAILED DESCRIPTION

The invention will now be described with reference to illustrative embodiments and to the accompanying figures. The embodiments described herein are intended to provide enabling support for the claimed subject matter and should not be construed as limiting unless expressly recited in the claims.

The disclosed invention is directed to methods of growing low-bandgap Hg1-xCdxTe by vapor-phase epitaxy using a surfactant-mediated morphology-control treatment during growth. In preferred embodiments, the vapor-phase epitaxy is MOVPE and the surfactant treatment comprises periodic gold deposition, a gold-containing precursor pulse, or another gold-containing surface exposure so that the gold acts as a surfactant and induces self-ordered (113)B facets in the growing Hg1-xCdxTe film. In broader embodiments, the treatment induces an ordered high-index faceted morphology that improves minority-carrier lifetime relative to Hg1-xCdxTe grown without the treatment. The disclosed methods are particularly useful for forming Hg1-xCdxTe films for photovoltaic devices operating in the long-wave infrared regime, and may also be used for thermophotovoltaic, detector, and other long-wave infrared optoelectronic devices.

The disclosed methods and devices provide a technical improvement over conventional low-bandgap Hg1-xCdxTe growth by repeatedly re-establishing an ordered high-index faceted morphology during continued epitaxy, thereby providing a measurable and reproducible increase in minority-carrier lifetime relative to control material grown without the periodic surfactant-mediated morphology-control treatment, and by enabling fabrication of photovoltaic devices exhibiting a dark current density and short-circuit current density meeting the operating-temperature and bias-window criteria recited in the claims. The technical improvement is grounded in the physical morphology of the grown film and in the resulting minority-carrier lifetime and dark-current improvements, rather than in mental steps or generic data manipulation.

As used herein, an ordered high-index faceted morphology includes repeated or spatially correlated faceted structures having crystallographic orientations other than ordinary low-index planar growth surfaces, and includes, in preferred embodiments, self-ordered (113)B facets. The morphology may be identified by atomic force microscopy, crystallographic characterization, repeated facet pitch, average facet height, or an improvement in minority-carrier lifetime relative to a control film.

As used herein, a low-bandgap Hg1-xCdxTe film in the long-wave infrared range includes a film having a bandgap selected to provide long-wave infrared response, with a preferred bandgap range of about 0.09 eV to about 0.11 eV. The term control film, unless otherwise indicated, refers to an Hg1-xCdxTe film grown under otherwise comparable vapor-phase epitaxy conditions but without the repeated surfactant-mediated morphology-control treatment.

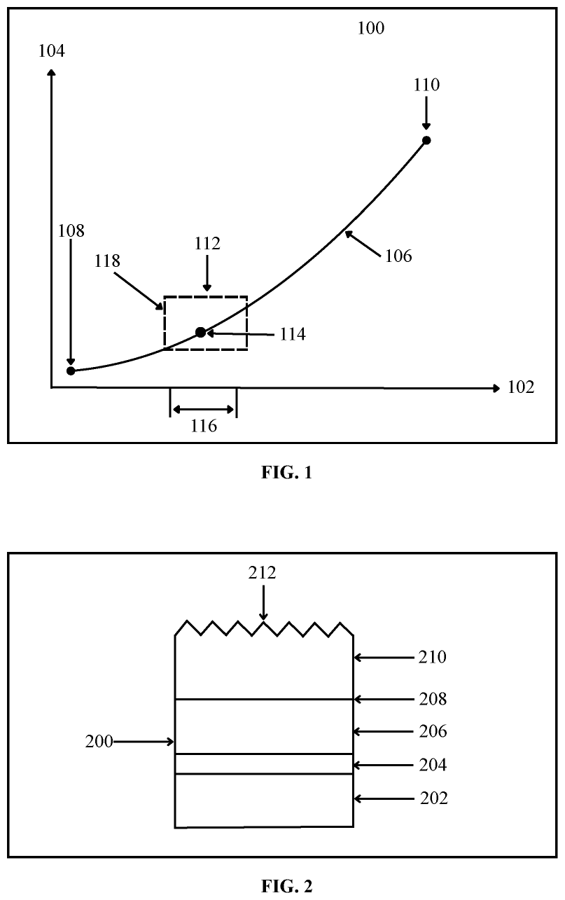

Referring to FIG. 1, a graph 100 is shown with a horizontal axis 102 corresponding to cadmium mole fraction x and a vertical axis 104 corresponding to bandgap Eg in eV. A bandgap curve 106 illustrates the dependence of bandgap on composition between an HgTe-side endpoint 108 and a CdTe-side endpoint 110. A target low-bandgap region 112 identifies compositions suitable for long-wave photovoltaic operation, and a preferred design point 114 corresponds to a bandgap of about 0.10 eV. In representative implementations, a preferred composition range 116 is selected so that the resulting material has a cut-off wavelength annotation 118 in the long-wave infrared regime.

FIG. 1 thus illustrates that the disclosed composition-selection window is not merely a generic narrow-bandgap operating region, but a practical design region for forming Hg1-xCdxTe films suitable for long-wave photovoltaic response. In preferred implementations, the graph supports selection of cadmium mole fraction x to obtain a target bandgap near about 0.10 eV while preserving flexibility across a broader range of about 0.09 eV to about 0.11 eV. The illustrated preferred design point 114 is exemplary, and adjacent compositions within the disclosed range may be selected for different operating temperatures, cut-off wavelengths, or device-performance targets.

In further embodiments, the bandgap-selection framework shown in FIG. 1 may be used for long-wave infrared optoelectronic devices formed from the disclosed film, with photovoltaic devices being a preferred implementation. The graphical relationship between composition and bandgap may also be used to select films for different long-wave response targets while maintaining the morphology-control techniques described herein.

Bandgap selection for Hg1-xCdxTe may be guided using the Hansen relation: Eg(x,T)=−0.302+1.93x−0.810x\hat{ }2+0.832x\hat{ }3+5.35×\hat{ }10−4×T×(1−2×), where x is cadmium mole fraction and T is temperature in Kelvin. In preferred embodiments, x is selected to provide an absorber bandgap in the range of about 0.09 eV to about 0.11 eV, and more preferably about 0.10 eV, corresponding to a cut-off wavelength in the long-wave infrared regime.

Referring to FIG. 2, a partially grown HgCdTe structure 200 is shown on a substrate 202 with an optional buffer 204. A previously grown HgCdTe portion 206 is present before a surfactant treatment region 208 is introduced. In preferred embodiments, the surfactant treatment region 208 is a deposited gold layer. In other embodiments, the surfactant treatment region 208 represents a gold-containing precursor exposure, gold-containing surface treatment, or other morphology-control treatment applied to the growth surface. After the treatment, resumed HgCdTe growth forms an overgrown portion 210 in which ordered high-index facets 212 are induced. In preferred embodiments, the ordered high-index facets 212 are self-ordered (113)B facets. These numerals identify representative structural features associated with periodic surfactant treatment during epitaxial growth.

FIG. 2 illustrates the role of the surfactant treatment region 208 as a morphology-modifying treatment applied between successive vapor-phase growth portions rather than merely as a static additive. The overgrown portion 210 demonstrates that resumed epitaxial growth after the surfactant treatment induces and propagates the preferred ordered high-index faceted morphology 212 into subsequently grown film material. As used herein, ordered high-index faceted morphology includes repeated, ordered facet structures appearing on the grown Hg1-xCdxTe surface after resumed growth following the surfactant treatment and identifiable, in representative embodiments, by AFM characterization, crystallographic characterization, facet height, facet pitch, or minority-carrier lifetime improvement relative to a control film. In preferred embodiments, the ordered faceting referred to herein is the self-ordered (113)B facet morphology induced by periodic gold deposition during growth of low-bandgap Hg1-xCdxTe.

As used herein, “ordered high-index faceted morphology” refers to a repeated or spatially correlated faceted surface morphology having facet orientations that are distinguishable from random roughness and that include crystallographic planes other than conventional low-index (100), (110), or (111) planes. In preferred embodiments, the ordered high-index faceted morphology comprises self-ordered (113)B facets. The presence, orientation, and order of the facets may be determined by atomic force microscopy, scanning electron microscopy, transmission electron microscopy, x-ray diffraction, electron backscatter diffraction, reflection high-energy electron diffraction, or another surface or crystallographic characterization technique. In representative embodiments, the morphology may be characterized by one or more of average facet height, facet pitch, facet density, facet orientation, surface roughness, or spatial correlation of adjacent facets.

In one preferred implementation, the substrate 202 is a CdZnTe wafer and the buffer 204 is a CdTe buffer layer formed before growth of the HgCdTe portion 206. The provisional disclosure describes CdZnTe (211)B wafers having a 2 degree miscut toward [01-1] and a thickness of about 600 microns, together with a CdTe buffer layer grown at about 380 degrees C. These substrate and buffer conditions are representative of preferred implementations of the disclosed process.

Unless otherwise indicated, comparison to control material or control films refers to Hg1-xCdxTe grown under otherwise comparable MOVPE conditions, including the same target bandgap range, generally comparable substrate and buffer configuration, and generally comparable film thickness, except without the periodic gold deposition used to induce the self-ordered (113)B facets. This comparative framework applies to the lifetime and device-performance improvements discussed herein.

The substrate and buffer arrangement associated with FIG. 2 is illustrative of one preferred implementation and may be varied while preserving the periodic surfactant-treatment growth architecture described herein. In alternative embodiments, the substrate, buffer thickness, orientation, miscut, or epitaxy platform may be adjusted so long as the growth sequence continues to support induction of ordered high-index faceted morphology and improved minority-carrier lifetime relative to control material grown without the surfactant treatment.

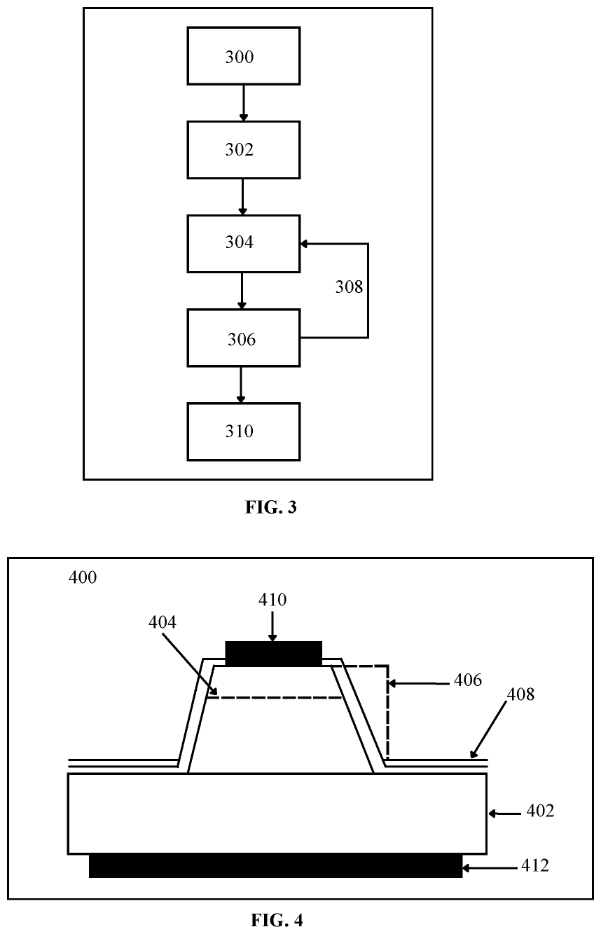

Referring to FIG. 3, an illustrative vapor-phase epitaxy sequence begins with substrate and buffer preparation at 300. Growth of a first HgCdTe portion is carried out at 302. A surfactant treatment step is carried out at 304, preferably a gold-containing treatment such as gold deposition or a gold-containing precursor pulse. Growth of HgCdTe is resumed at 306. In preferred implementations, the surfactant treatment and resumed growth are repeated one or more times, as indicated at 308, until a desired film thickness is obtained. A completed low-bandgap HgCdTe film suitable for photovoltaic device fabrication is indicated at 310.

FIG. 3 accordingly depicts a segmented-growth architecture in which repeated interruption of film growth permits repeated surface treatment and repeated re-establishment of the desired morphology during continued epitaxy. The illustrated sequence is particularly useful for maintaining morphology control over films grown to practical absorber thicknesses and for producing a film that may be used directly as a claimed material output or subsequently incorporated into a device structure.

In the provisional disclosure, a preferred sequence includes growing about 400 nm of Hg1-xCdxTe at about 345 degrees C, cooling to about 250 degrees C, pulsing AuCl(CO)(PEt3), and then resuming HgCdTe growth, with repetition after each additional 400 nm of growth. More generally, the periodic surfactant treatment may be repeated after about 300 nm to about 500 nm of Hg1-xCdxTe growth, and in some embodiments after about 350 nm to about 450 nm of growth. Thus, in claim-tracking terms, preferred implementations include growing a first portion of the Hg1-xCdxTe film by vapor-phase epitaxy, exposing the growth surface to a surfactant treatment, resuming epitaxial growth after the treatment, and repeating the treatment and resumed-growth sequence one or more times so that the repeated sequence induces ordered high-index facets in the Hg1-xCdxTe film. In more particular implementations, the vapor-phase epitaxy is MOVPE, the surfactant treatment is gold deposition, and the ordered high-index facets are self-ordered (113)B facets. The interval between successive surfactant-mediated morphology-control treatments may be selected according to film thickness, growth time, observed surface reconstruction, surface roughness, facet degradation, target absorber thickness, or desired spacing between treatment-interface regions. In some embodiments, the treatment interval is between about 100 nm and about 1000 nm of HgCdTe growth, between about 200 nm and about 700 nm, between about 300 nm and about 500 nm, between about 350 nm and about 450 nm, or about 400 nm. In other embodiments, the treatment may be applied periodically, intermittently, in response to an observed or predicted morphology change, or according to elapsed growth time rather than solely according to thickness. In further embodiments, the surfactant treatment may be pulsed, repeated, quasi-continuous during selected growth windows, or applied as a plurality of discrete surface treatments separated by resumed HgCdTe growth. Treatment intervals materially below the disclosed 300 nm to 500 nm window produce excess incorporated gold and degrade resumed-growth quality, while intervals materially above the disclosed window result in loss of self-ordered (113)B faceting and progressive morphology regression in subsequently grown material. Accordingly, in preferred embodiments the interval is selected within the disclosed 300 nm to 500 nm window, and more particularly at about 400 nm, to maintain self-ordered (113)B faceting and at least five-fold lifetime improvement through a practical absorber thickness.

In representative implementations, the surfactant treatment step is carried out after completion of a prior Hg1-xCdxTe growth portion and before resumed growth of a subsequent Hg1-xCdxTe growth portion, so that each repeated treatment step operates as an interposed morphology-control step within the segmented growth sequence. The repeated interposition of the surfactant treatment step between successive growth portions is a preferred aspect of the disclosed method.

The process-flow representation of FIG. 3 is also intended to convey that the surfactant treatment step may be repeated one or more times as needed to obtain a selected film thickness while repeatedly re-establishing the preferred ordered high-index faceted morphology during resumed growth. In preferred implementations, control of the resulting film morphology is achieved by coordinated selection of surfactant material, deposited amount or exposure dose, interval between successive treatments, reactor pressure, substrate temperature, and resumed growth conditions.

In certain embodiments, the disclosed process tolerates variation around the preferred deposited-gold thickness, gold exposure dose, interval between successive treatment steps, reactor pressure, substrate temperature, and resumed-growth conditions, provided that the repeated treatment-and-growth sequence continues to induce the preferred ordered high-index faceted morphology in the Hg1-xCdxTe film. Accordingly, the preferred values described herein may be used as target operating conditions, while neighboring values that preserve the disclosed morphology and film performance remain within the contemplated process window.

In certain embodiments, process qualification for the disclosed film includes confirming that the film remains within the disclosed bandgap range of about 0.09 eV to about 0.11 eV and that the periodic surfactant treatment produces the preferred ordered high-index faceted morphology, for example by AFM characterization of representative films, by crystallographic characterization of facet orientation, by measuring facet height or pitch, and by comparison of minority-carrier lifetime or device performance to control material grown without the surfactant treatment. In this manner, the repeated surfactant-treatment architecture provides both a growth sequence and a repeatable manufacturing control framework for producing the disclosed film and devices.

In representative embodiments, the surfactant treatment comprises deposited gold corresponding to a thickness between about 1 nm and about 3 nm, with about 2 nm being a preferred example. In other embodiments, the treatment is characterized by a gold-containing precursor exposure dose or by an areal density of gold at or near the growth surface sufficient to induce the ordered high-index faceted morphology. AFM characterization in the provisional disclosure shows self-ordered (113)B facets 212 having a height of about 12 nm. The invention is not limited by any particular theory of operation; however, in preferred embodiments the induced facet morphology is associated with improved minority-carrier lifetime relative to control material grown without the periodic surfactant treatment.

In embodiments using a gold-containing precursor pulse, the pulse may be applied for a duration selected to provide an amount of gold-containing material sufficient to modify resumed HgCdTe growth without converting the treatment into a continuous bulk layer. In representative embodiments, the precursor exposure may be applied for about 1 second to about 300 seconds, about 5 seconds to about 120 seconds, or about 10 seconds to about 60 seconds. The treatment step may be followed by a purge or stabilization interval before resumed HgCdTe growth. During cooling, treatment, purge, or resumed growth, one or more Hg-containing, Te-containing, inert, hydrogen, or carrier-gas environments may be maintained to reduce mercury loss, stabilize the growth surface, or preserve the desired surface reconstruction. In some embodiments, the growth temperature is ramped from the HgCdTe growth temperature to the treatment temperature before the gold-containing treatment is applied and is then returned to the HgCdTe growth temperature before resumed growth.

In certain embodiments, the disclosed Hg1-xCdxTe film is itself a claimed product independent of subsequent device fabrication. Such a film may be characterized by one or more of: a bandgap between about 0.09 eV and about 0.11 eV, formation by vapor-phase epitaxy with periodic surfactant treatment during growth, self-ordered (113)B facet morphology or other ordered high-index faceted morphology induced by the treatment, a preferred facet height of about 12 nm in representative embodiments, gold or gold-containing material localized at treatment interfaces or near the growth surface, and minority-carrier lifetime improved relative to control Hg1-xCdxTe grown without the periodic surfactant treatment. In further embodiments, the film includes a surface region bearing the ordered high-index facets and an underlying grown Hg1-xCdxTe body produced by the repeated treatment-and-growth sequence described herein. The film may therefore be recovered, transferred, stored, characterized, or subsequently incorporated into a photovoltaic device while retaining the structural and process-origin characteristics described herein.

In some embodiments, the repeated surfactant-mediated morphology-control treatment forms a plurality of spaced treatment-interface regions within the Hg1-xCdxTe film. Each treatment-interface region may correspond to a growth interruption, deposited surfactant layer, surfactant-enriched region, precursor-exposure region, or compositional transition region associated with one of the repeated treatment steps. Where a gold-containing treatment is used, gold or gold-containing material may remain localized at or near one or more of the treatment-interface regions, may be present as an interfacial enrichment, or may be distributed over a finite thickness adjacent to the interface. The presence or relative localization of gold or gold-containing material may be detected by secondary ion mass spectrometry, transmission electron microscopy with energy-dispersive spectroscopy, atom probe tomography, x-ray photoelectron spectroscopy, Auger electron spectroscopy, Rutherford backscattering, or another compositional profiling technique.

In further embodiments, the disclosed film is characterized structurally by a faceted surface region bearing ordered high-index facets, including self-ordered (113)B facets in preferred embodiments, and by an underlying Hg1-xCdxTe body grown beneath the faceted surface region by the repeated vapor-phase growth and surfactant-treatment sequence. In representative embodiments, the faceted surface region and the underlying Hg1-xCdxTe body together define a film structure distinguishable from control Hg1-xCdxTe grown without the periodic surfactant treatment.

In additional structural embodiments, the film includes a plurality of spaced treatment-interface regions corresponding to repeated surfactant-mediated morphology-control treatments applied during growth. In gold-containing embodiments, gold or gold-containing material may be localized at the spaced treatment-interface regions, and adjacent treatment-interface regions may be separated by the thickness of an intervening Hg1-xCdxTe growth portion, for example by about 300 nm to about 500 nm and preferably about 400 nm. Such spaced treatment-interface regions provide a structural signature of the repeated treatment-and-growth sequence.

In preferred implementations, atomic force microscopy shows self-ordered (113)B facets having an average height in the disclosed 5 nm to 25 nm range, and in representative examples about 12 nm.

In certain embodiments, the gold-induced (113)B facet morphology or broader surfactant-induced high-index faceted morphology is associated with suppression of vacancy-mediated recombination effects. The provisional disclosure reports minority-carrier lifetime of 34 ns for golden-terrace material versus 3.1 ns for conventional material in one photoluminescence comparison, and further reports a 6.9× lifetime improvement at 200 K. In some embodiments, the disclosed process provides an increase in minority-carrier lifetime of at least five-fold relative to Hg1-xCdxTe grown without the periodic surfactant treatment.

Without being bound by theory, the periodically interposed gold-containing treatment is believed to alter resumed epitaxial growth in a manner that reduces recombination pathways associated with conventional low-bandgap HgCdTe material. The observed lifetime improvement relative to otherwise comparable control material supports the use of the repeated treatment sequence as a morphology-control and lifetime-improvement technique rather than as a merely incidental surface exposure.

In preferred process conditions, MOVPE growth is carried out at a reactor pressure of about 40 Torr and a substrate temperature of about 345 degrees C. The provisional disclosure further identifies Me2Te and Et2Hg precursors, CdCl2 as a cadmium source, and AsH3 at 4 ppm for p-type doping. These conditions may be used in preferred implementations of the disclosed growth method.

Referring to FIG. 4, a representative photovoltaic device 400 includes an Hg1-xCdxTe film 402 formed according to the disclosed growth methods. In the illustrated embodiment, a p-on-n diode structure 404 is formed on the film 402. A mesa region 406 is defined in the device structure. An anti-reflection coating 408 is disposed over the active device region. A top contact 410 is formed on the device, and a backside contact 412 is formed on an opposing side of the structure. Methods of fabricating photovoltaic devices according to the present disclosure include forming a diode structure from the disclosed Hg1-xCdxTe film 402 and, in preferred embodiments, forming the p-on-n diode structure 404 and further defining the mesa region 406 and applying the anti-reflection coating 408 and contacts 410, 412. These numerals identify representative structural features of a preferred photovoltaic embodiment and are not intended to limit the invention to a particular device layout unless expressly recited in the claims.

As used herein, a diode structure formed from the disclosed Hg1-xCdxTe film refers to a photovoltaic junction structure configured for carrier separation and collection from the disclosed film, with a p-on-n diode structure being a preferred implementation and a p-on-n mesa diode being a more specific preferred implementation. The disclosed device-fabrication methods accordingly include both formation of the junction-bearing device structure from the disclosed film and integration of optional structural features such as the mesa region 406, anti-reflection coating 408, top contact 410, and backside contact 412.

In further embodiments, the diode structure may include other photovoltaic junction-bearing structures formed from the disclosed Hg1-xCdxTe film, provided that the structure remains configured for carrier separation and collection from the disclosed film. The p-on-n diode structure and p-on-n mesa diode remain preferred implementations. Alternative structures include n-on-p junctions, p-i-n junctions, nBn structures, barrier-type photovoltaic structures, heterojunction structures, planar diodes, and mesa diodes, each of which may be selected according to carrier collection, dark current, passivation, or fabrication requirements.

FIG. 4 should be understood as illustrating one preferred device realization of the disclosed film rather than the only device format in which the film may be used. The illustrated diode structure 404 shows a preferred carrier-collection architecture for photovoltaic operation, while the disclosed film may also be incorporated into related long-wave infrared optoelectronic device structures in alternative embodiments, including detector, thermophotovoltaic, and photovoltaic structures. The mesa region 406, anti-reflection coating 408, and contacts 410 and 412 are representative integration features that may be modified according to packaging, biasing, or fabrication requirements.

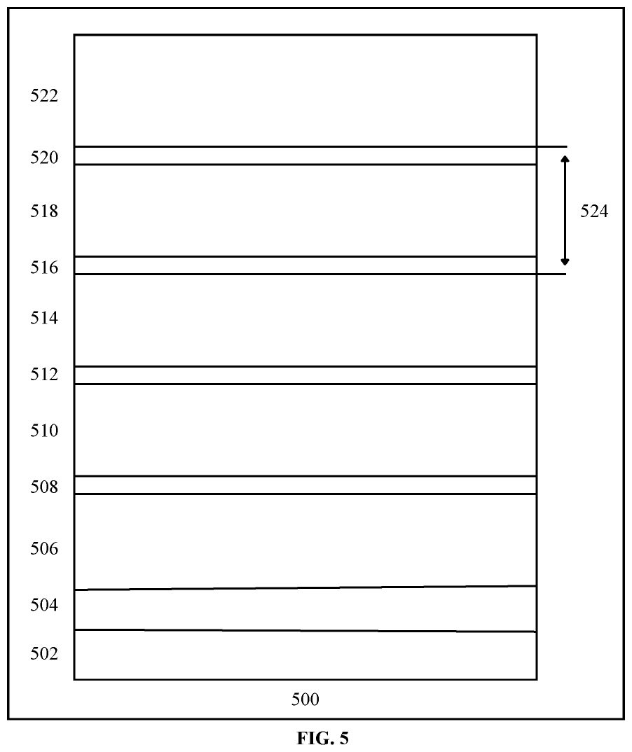

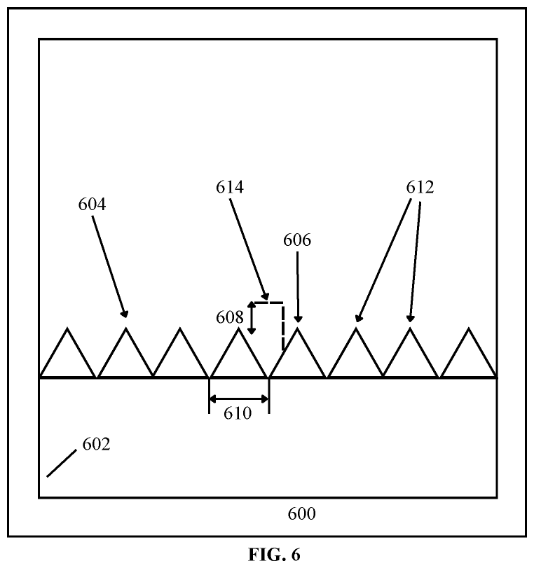

Referring to FIG. 5, a multilayer Hg1-xCdxTe structure 500 is shown including a substrate 502, an optional buffer 504, a plurality of Hg1-xCdxTe growth portions 506, 510, 514, 518, and 522, and a plurality of treatment-interface regions 508, 512, 516, and 520 corresponding to repeated surfactant-mediated morphology-control treatments during growth. Representative spacing between adjacent treatment-interface regions is indicated at 524. In preferred implementations, each treatment-interface region corresponds to an interposed morphology-control treatment applied after growth of a preceding Hg1-xCdxTe portion and before resumed growth of a subsequent Hg1-xCdxTe portion. In gold-containing embodiments, one or more of the treatment-interface regions 508, 512, 516, and 520 may comprise deposited gold, a gold-containing precursor-exposure region, a surfactant-enriched region, an interfacial enrichment, or a finite-thickness region in which gold or gold-containing material is localized relative to adjacent Hg1-xCdxTe material. The representative spacing 524 may correspond to the thickness of an intervening Hg1-xCdxTe growth portion and, in certain embodiments, may be between about 100 nm and about 1000 nm, between about 200 nm and about 700 nm, between about 300 nm and about 500 nm, between about 350 nm and about 450 nm, or about 400 nm. FIG. 5 is schematic and is not intended to require any particular number of treatment-interface regions, any particular relative layer thickness, or continuous retention of a discrete gold layer unless expressly recited in the claims. In particular claimed embodiments, the plurality of treatment-interface regions 508, 512, 516, and 520 include localized gold or gold-containing material, and adjacent treatment-interface regions are separated by about 300 nm to about 500 nm of intervening Hg1-xCdxTe material, thereby providing a compositional and spatial fingerprint of the repeated gold-containing treatment-and-growth sequence. Referring to FIG. 6, an enlarged structure 600 is shown including an Hg1-xCdxTe body 602 and an ordered high-index faceted surface region 604. A representative individual high-index facet is indicated at 606, average facet height is indicated at 608, facet pitch is indicated at 610, facet orientation is indicated at 612, and self-ordered facet morphology is indicated at 614. In preferred implementations, the ordered high-index faceted surface region 604 comprises self-ordered (113)B facets induced by the repeated surfactant-mediated morphology-control treatment described herein. The average facet height 608, facet pitch 610, and facet orientation 612 may be determined by atomic force microscopy, scanning electron microscopy, transmission electron microscopy, x-ray diffraction, electron backscatter diffraction, reflection high-energy electron diffraction, or another surface or crystallographic characterization technique. In representative embodiments, the average facet height 608 is between about 5 nm and about 25 nm, and in preferred examples is about 12 nm. FIG. 6 is schematic and is not intended to limit the ordered high-index faceted morphology to any particular pitch, facet angle, number of facets, or exact geometric profile unless expressly recited in the claims.

In one representative embodiment described in the provisional disclosure, the photovoltaic device comprises a p-on-n mesa diode having an Hg1-xCdxTe absorber layer with a thickness of about 3.5 microns. Representative fabrication steps include wet-etching a mesa in Br2/methanol to a depth of about 600 nm, depositing a ZnS/SiO2 anti-reflection coating having a thickness of about 1.2 microns, forming a Ti/Au ring contact at about 20/200 nm, and forming an indium backside n-contact.

The provisional disclosure reports that a device fabricated on the disclosed film produces a short-circuit current density of about 0.366 A/cm\hat{ }2 at 200 K and an open-circuit voltage of about 42 mV at 120 K. The provisional further reports a dark current density of about 2.1×10\hat{ }−5 A/cm\hat{ }2 at 150 K and 200 mV bias, and provides support for devices exhibiting a dark current density of not more than 3×10\hat{ }−5 A/cm\hat{ }2 at 150 K and 200 mV bias, and for devices yielding a short-circuit current density of at least 0.3 A/cm\hat{ }2 at 200 K under a 400 K to 600 K black-body source.

Minority-carrier lifetime may be measured using time-resolved photoluminescence, transient photoconductivity, microwave photoconductive decay, or another lifetime-characterization technique suitable for low-bandgap HgCdTe. In representative comparisons, treated films and control films are preferably measured at comparable temperature, excitation conditions, carrier-injection level, film thickness, bandgap, substrate configuration, and surface-passivation condition. A lifetime improvement may be determined by comparing a treated film produced using the repeated surfactant-mediated morphology-control treatment with a control film grown under otherwise comparable conditions without the repeated treatment.

Dark current density may be measured using a photovoltaic diode or mesa diode formed from the disclosed film at a specified device temperature and applied bias, with current normalized to active device area. Short-circuit current density may be measured under a calibrated black-body source or other long-wave infrared illumination source, with the device maintained at a selected operating temperature. In representative embodiments, black-body source temperature, device temperature, optical coupling geometry, active area, and measurement bandwidth may be selected and recorded so that treated and control devices can be compared under substantially equivalent test conditions.

The disclosed methods and devices may be used in long-wave photovoltaic applications, including thermophotovoltaic conversion of radiation from waste-heat sources and other long-wave infrared sources. The provisional disclosure identifies potential applications including 400 K to 600 K thermophotovoltaic waste-heat recovery, space infrared power scavenging at 120 K to 200 K, uncooled 8-14 micron photovoltaic focal plane arrays, and mid-infrared geothermal energy harvesters. Such applications are illustrative and do not limit the scope of the claims.

More generally, the disclosed films and device structures may be employed in long-wave infrared optoelectronic applications in which the ordered high-index faceted morphology and corresponding lifetime improvement provide operational benefit, with photovoltaic implementations being preferred. The listed applications are therefore exemplary deployment paths for the disclosed film and device architecture rather than an exclusive statement of use.

What is claimed is:

1. A method of growing a low-bandgap mercury cadmium telluride film, comprising: growing a first portion of an Hg1-xCdxTe film by vapor-phase epitaxy under conditions selected to provide a bandgap in a long-wave infrared range; applying, after growth of the first portion, a surfactant-mediated morphology-control treatment to a growth surface of the Hg1-xCdxTe film; resuming epitaxial growth of the Hg1-xCdxTe film after the surfactant-mediated morphology-control treatment; and repeating the applying and resuming steps one or more times during growth of the Hg1-xCdxTe film, wherein the repeated surfactant-mediated morphology-control treatment induces an ordered high-index faceted morphology in the Hg1-xCdxTe film.

2. The method of claim 1, wherein the surfactant-mediated morphology-control treatment comprises a gold-containing surfactant treatment.

3. The method of claim 2, wherein the gold-containing surfactant treatment comprises depositing gold onto the growth surface in a thickness between 1 nm and 3 nm, or exposing the growth surface to a gold-containing precursor pulse comprising AuCl(CO)(PEt3).

4. The method of claim 1, wherein the applying and resuming steps are repeated after each 300 nm to 500 nm of Hg1-xCdxTe growth.

5. The method of claim 1, wherein the Hg 1-xCdxTe film has a bandgap between 0.09 eV and 0.11 eV.

6. The method of claim 1, wherein the vapor-phase epitaxy comprises metal-organic vapor-phase epitaxy (MOVPE) carried out at a reactor pressure of about 40 Torr and a substrate temperature of about 345 degrees C.

7. The method of claim 6, wherein the MOVPE uses Me2Te and Et2Hg precursors, CdCl2 as a cadmium source, and AsH3 for p-type doping.

8. The method of claim 3, further comprising cooling the growth surface to about 250 degrees C before applying the gold-containing precursor pulse.

9. The method of claim 1, wherein the ordered high-index faceted morphology comprises self-ordered (113)B facets.

10. The method of claim 9, wherein the self-ordered (113)B facets have an average facet height between 5 nm and 25 nm as measured by atomic force microscopy.

11. The method of claim 1, wherein the ordered high-index faceted morphology is associated with an increase in minority-carrier lifetime of at least five-fold relative to a control Hg1-xCdxTe film grown without the repeated surfactant-mediated morphology-control treatment.

12. The method of claim 11, wherein the control Hg1-xCdxTe film is grown under otherwise comparable vapor-phase epitaxy conditions, with a comparable target bandgap range and comparable film thickness, except without the repeated surfactant-mediated morphology-control treatment.

13. The method of claim 2, wherein gold or gold-containing material is localized at one or more treatment interfaces associated with the repeated surfactant-mediated morphology-control treatment.

14. A method of growing a low-bandgap Hg1-xCdxTe film by metal-organic vapor-phase epitaxy (MOVPE), comprising: growing successive Hg1-xCdxTe portions having a bandgap between about 0.09 eV and about 0.11 eV; after each about 300 nm to about 500 nm of Hg1-xCdxTe growth, applying a gold-containing surfactant treatment comprising deposited gold or an AuCl(CO)(PEt3) precursor pulse; resuming MOVPE growth after each gold-containing surfactant treatment; and thereby inducing self-ordered (113)B facets in the Hg1-xCdxTe film.

15. The method of claim 14, wherein the self-ordered (113)B facets have an average facet height between about 5 nm and about 25 nm, and wherein the gold-containing surfactant treatment is applied after cooling the growth surface to about 250 degrees C.

16. A photovoltaic device comprising: an Hg1-xCdxTe absorber film having a bandgap in a long-wave infrared range, the absorber film comprising an ordered high-index faceted morphology induced by repeated surfactant-mediated morphology-control treatment during epitaxial growth of the absorber film; and a photovoltaic junction structure formed from the Hg1-xCdxTe absorber film.

17. The photovoltaic device of claim 16, wherein the absorber film has a bandgap between 0.09 eV and 0.11 eV and the ordered high-index faceted morphology comprises self-ordered (113)B facets.

18. The photovoltaic device of claim 16, wherein the repeated surfactant-mediated morphology-control treatment comprises a gold-containing treatment selected from gold deposition and a gold-containing precursor pulse.

19. The photovoltaic device of claim 16, wherein the photovoltaic junction structure comprises a p-on-n diode structure, an n-on-p diode structure, a p-i-n junction structure, an nBn structure, a barrier-type photovoltaic structure, or a heterojunction structure.

20. The photovoltaic device of claim 19, wherein the photovoltaic junction structure comprises a p-on-n mesa diode having an Hg1-xCdxTe absorber layer with a thickness of about 3.5 microns, a mesa etched to a depth of about 600 nm, an anti-reflection coating, a top contact, and a backside contact.

21. The photovoltaic device of claim 16, wherein the photovoltaic device exhibits a dark current density of not more than 3×10\hat{ }−5 A/cm\hat{ }2 at 150 K and 200 mV bias.

22. The photovoltaic device of claim 16, wherein the photovoltaic device yields a short-circuit current density of at least 0.3 A/cm\hat{ }2 at 200 K under a 400 K to 600 K black-body source.

23. A Hg1-xCdxTe film having a bandgap in a long-wave infrared range, the film comprising: an Hg1-xCdxTe body formed by vapor-phase epitaxy; and an ordered high-index faceted surface region induced by periodic surfactant-mediated morphology-control treatment during growth, wherein the ordered high-index faceted surface region is associated with increased minority-carrier lifetime relative to a control Hg1-xCdxTe film grown without the periodic surfactant-mediated morphology-control treatment.

24. The Hg1-xCdxTe film of claim 23, wherein the film has a bandgap between 0.09 eV and 0.11 eV, and wherein the ordered high-index faceted surface region comprises self-ordered (113)B facets having an average facet height between 5 nm and 25 nm.

25. The Hg1-xCdxTe film of claim 23, wherein the Hg1-xCdxTe body comprises a plurality of spaced treatment-interface regions within the Hg1-xCdxTe body, wherein gold or gold-containing material is localized at the plurality of spaced treatment-interface regions, and wherein adjacent ones of the spaced treatment-interface regions are separated by about 300 nm to about 500 nm of intervening Hg1-xCdxTe material.

26. The Hg1-xCdxTe film of claim 25, wherein the gold or gold-containing material localized at the plurality of spaced treatment-interface regions is detectable by secondary ion mass spectrometry, transmission electron microscopy with energy-dispersive spectroscopy, atom probe tomography, x-ray photoelectron spectroscopy, Auger electron spectroscopy, Rutherford backscattering, or another compositional profiling technique.

27. The Hg1-xCdxTe film of claim 24, wherein the ordered high-index faceted surface region is characterized by atomic force microscopy or crystallographic characterization as comprising self-ordered (113)B facets having an average facet height of about 12 nm.
